(19) United States
(12) Patent Application Publication
(10) Pub. No.: US 2008/0224013 A1
(43) Pub. Date: Sep. 18, 2008

(54) Ceiling Fan Mounting System

(76) Inventor: Shih Chu Huang, Taichung (TW)

Correspondence Address: HDSL, 4331 STEVENS BATTLE LANE, FAIRFAX, VA, 22033, US

(21) Appl. No.: 11/686,745

(22) Filed: Mar. 15, 2007

(51) Int. Cl. H05K 5/02

(52) U.S. Cl. 248/343; 248/345

(57) ABSTRACT

A ceiling fan mounting system includes a mounting bracket for fixing the ceiling fan mounting system, and a canopy. The mounting bracket includes a flange comprising an external peripheral surface, the external peripheral surface having at least one locking hole thereat. The canopy includes a sleeve joint adapted to receive and nest the flange of the mounting bracket. The canopy has at least one elastic blocker corresponding the at least one locking hole, in assembly, the at least one elastic blocker being embedded in the at least one locking hole.

### BACKGROUND

The present invention relates to a ceiling fan mounting system, especially relates to a ceiling fan mounting system, easy to be assembled or disassembled.

Recently, with more attentions toward protecting the natural environment and saving energy source, ceiling fan have become an increasingly popular supplementary means of creating an airflow within both commercial and residential buildings. The ceiling fans can decrease the concentration of hot and cold air at the ceiling, which can further lower the room temperature in an air conditioning room and save the energy consumption. In addition, some good-shape ceiling fans can decorate the room.

For maintaining needs of installation and ornamentation of the ceiling fans, a typical ceiling fans mounting systems is shown in FIG. 1 and FIG. 2. The mounting system has a mounting bracket 50 and a canopy 60 having a special shape covering the mounting bracket 50. The mounting bracket 50 has a supporting element 51 defining an opening 52, a wing portion 55 extending from a top portion of the supporting element 51. The wing portion 55 is used to mount the mounting bracket 50 directly or indirectly on the ceiling. The canopy 60 has a canopy flange 61 adapted to receive and nest a peripheral surface 56 of the wing portion 55. The canopy 60 is fixed on the mounting bracket 50 through threading a plurality of screws 66 respectively through a plurality of through holes 65 at the canopy flange 61 and into a plurality of screw holes 57 formed at the peripheral surface 56 of the wing portion 55.

In use, the assembly process or the disassembly process needs firstly aligning the plurality of through holes 65 and the plurality of screw holes 57, respectively; and then screwing in or screwing out the plurality of screws 66 respectively. Thus, there is a noticeable increase in the difficulty of installing the ceiling fan assembly, in the time required for installation. In addition, for precise aligning the plurality of through holes 65 and the plurality of screw holes 57, respectively, the screw holes 57 needs two processes of drilling and cutting screw threads, which adds the manufacturing difficult and decreases the yield ratio. Moreover, after the screws 66 screw at the canopy 60 and the mounting bracket 50, the screws 66 is exposed, which destroys the beauty appearance.

Accordingly, what is needed is a ceiling fan mounting system that can overcome the above-described deficiencies.

### BRIEF SUMMARY

A ceiling fan mounting system includes a mounting bracket for fixing the ceiling fan mounting system, and a canopy. The mounting bracket includes a flange comprising an external peripheral surface, the external peripheral surface having at least one locking hole thereat. The canopy includes a sleeve joint adapted to receive and nest the flange of the mounting bracket. The canopy has at least one elastic blocker corresponding the at least one locking hole, in assembly, the at least one elastic blocker being embedded in the at least one locking hole.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is an exploded, schematic view of a conventional ceiling fan mounting system;

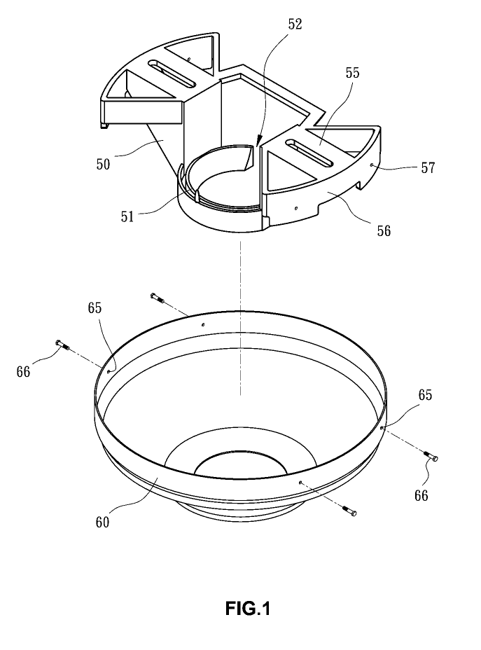

FIG. 2 is a cross-sectional view of the ceiling fan mounting system of FIG. 1;

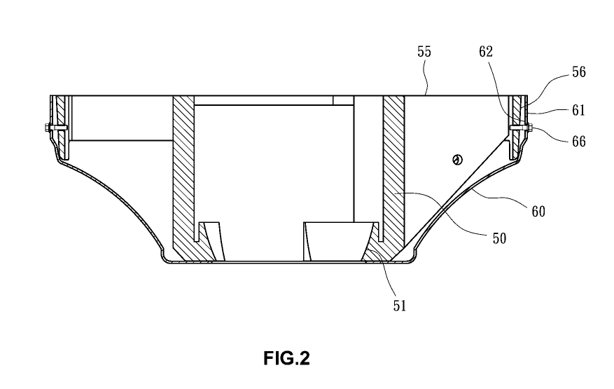

FIG. 3 is an exploded, schematic view of a ceiling fan mounting system according to a first embodiment of the present invention;

FIG. 4 is an assembly view of the ceiling fan mounting system of FIG. 3; and

FIG. 5 is a cross-sectional view of the ceiling fan mounting system of FIG. 4;

### DETAILED DESCRIPTION

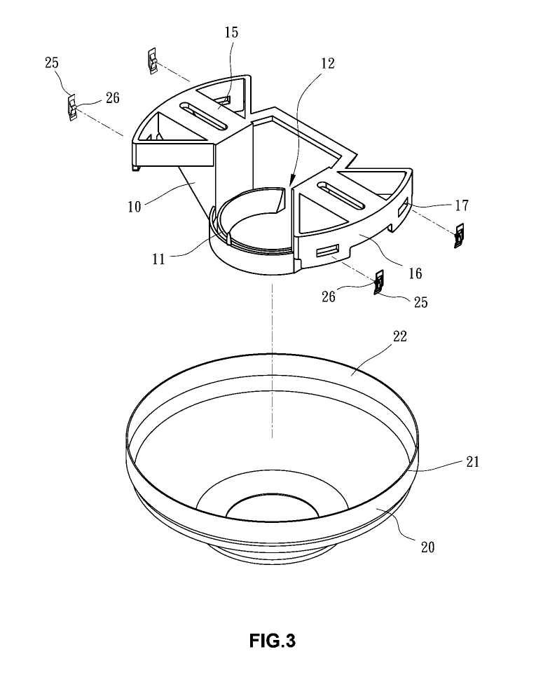

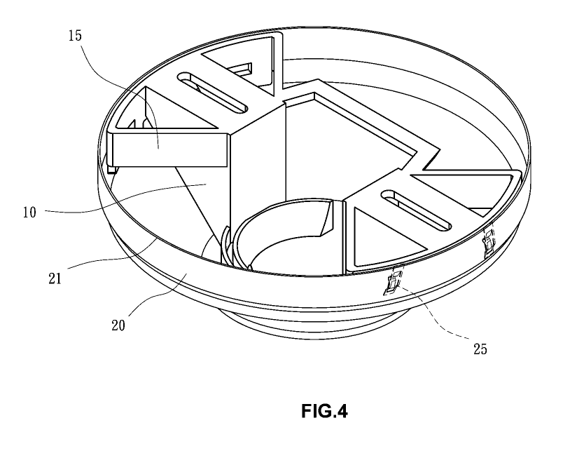

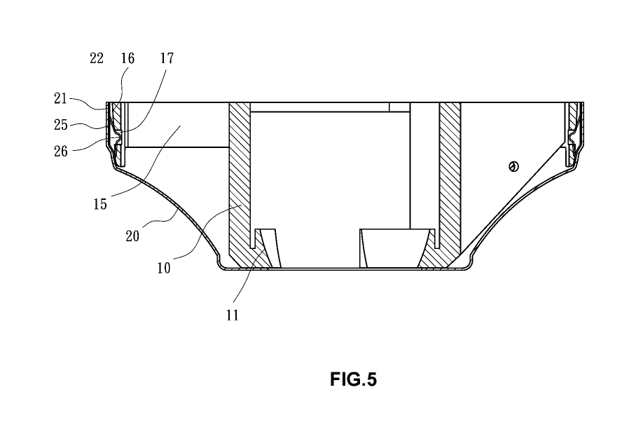

Referring to FIGS. 3-5, a ceiling fan mounting system includes a mounting bracket 10 used for mounting a ceiling fan on a ceiling; and a canopy 20 for covering the mounting bracket 10.

The mounting bracket 10 includes a supporting member 11 having an arc-shaped internal peripheral, a wing portion 15 extending outward from a top portion of the wing portion 15. The wing portion 15 has a planar surface as a contacting interface, for mounting on the ceiling, which has a peripheral, annular flange 16 extending downward from the planar surface. The annular flange 16 has at least one locking hole 17 for fixing the canopy thereon. In this embodiment, the annular flange 16 has four locking holes 17.

The canopy 20 has a special designs at its external peripheral surface, which has a sleeve joint 21 at a top portion of the canopy 20, adapted to receive and nest the annular flange 16 of the wing portion 15. In addition, the canopy 20 further has at least one elastic blocker 25. In this embodiment, the canopy 20 has four elastic blockers 25, corresponding to the four locking holes 17. Each elastic blocker 25 has an elastic protrusion 26 at a center portion thereof, formed by a U-shaped elastic piece, which can be elastically blocked in the locking hole 17 for fastening the canopy 20 at the mounting bracket 10.

In assembly, a user just needs respectively aligning the elastic blockers 25 of the canopy 20 with the locking holes 17 of the mounting bracket 10, and then upward pushing and pressing the canopy 20 toward the mounting bracket 10. Because the elastic blocker 25 has an elastic deformation characteristic, the canopy 20 can easily slides at the external peripheral surface and the elastic blocker 25 can slide into the locking holes 17, embedded therein. Thus the canopy 20 can be fixed at the mounting bracket 10 for the elastic deformation of the elastic protrusions 26 of the elastic blockers 25. In disassembly process, the user just needs downward push the canopy 20, the elastic protrusions 26 of the elastic blockers 25 can slide out from the locking holes 17 at the downward force, and the canopy 20 can be disassembled from the mounting bracket 10.

The ceiling fan mounting system utilizes an elastic blocker 25 to realize easily assembling and disassembling the canopy 20 and the mounting bracket 10. In addition, the canopy 20 or the mounting bracket 20 can be manufactured by mold casting integration method or mold pressing integration method. Thus, the process is easy and the yield ratio is improved. Moreover, the elastic blocker 25 is embedded into the locking holes 17 of the mounting bracket 10. Thus, the conventional screws are missed, which can add the beauty.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A ceiling fan mounting system, comprising:
a mounting bracket for fixing the ceiling fan mounting system, which comprises a flange comprising an external peripheral surface, the external peripheral surface having at least one locking hole thereat; and
a canopy having a sleeve joint adapted to receive and nest the flange of the mounting bracket;
wherein the canopy has at least one elastic blocker corresponding the at least one locking hole, in assembly, the at least one elastic blocker being embedded in the at least one locking hole.

2. The ceiling fan mounting system as claimed in claim 1, wherein number of the at least one elastic blocker is four, and number of the least one locking hole also is four.

3. The ceiling fan mounting system as claimed in claim 1, wherein each elastic blocker has an elastic protrusion at a center portion thereof.

4. The ceiling fan mounting system as claimed in claim 1, wherein the elastic protrusion is a U-shaped elastic piece, which can be elastically embedded in the locking hole for fastening the canopy at the mounting bracket.

5. The ceiling fan mounting system as claimed in claim 1, wherein the canopy can be upward pushed and pressed toward the mounting bracket for assembly.

6. The ceiling fan mounting system as claimed in claim 5, wherein the canopy can slide at the external peripheral surface of the mounting bracket.

7. The ceiling fan mounting system as claimed in claim 1, wherein the canopy can be disassembled from the mounting bracket through a downward force.

8. The ceiling fan mounting system as claimed in claim 1, wherein the canopy is fixed at the mounting bracket by the elastic deformation of the elastic protrusion of the elastic blocker.

9. The ceiling fan mounting system as claimed in claim 1, wherein the canopy or the mounting bracket can be manufactured by mold casting integration method or mold pressing integration method.
